(19) United States
(12) Patent Application Publication
(10) Pub. No.: US 2024/0212996 A1
(43) Pub. Date: Jun. 27, 2024

(54) SUBSTRATE SUPPORT AND PLASMA PROCESSING APPARATUS

(71) Applicant: Tokyo Electron Limited, Tokyo (JP)

(72) Inventors: Toshiyuki ARAKANE, Miyagi (JP); Hikaru KIKUCHI, Miyagi (JP); Naoyuki SATOH, Miyagi (JP); Shu KUSANO, Miyagi (JP)

(73) Assignee: Tokyo Electron Limited, Tokyo (JP)

(21) Appl. No.: 18/392,102

(22) Filed: Dec. 21, 2023

(30) Foreign Application Priority Data
Dec. 21, 2022 (JP) 2022-204837

(51) Int. Cl. H01J 37/32

(52) U.S. Cl. CPC H01J 37/32715; H01J 37/3266; H01J 37/32082; H01J 2237/2007

(57) ABSTRACT

A magnetic field in an outer peripheral portion of a substrate is controlled while protecting an adhesive layer of a substrate support. Provided is the substrate support including: a base; an electrostatic chuck provided on the base and having a substrate support surface for supporting a substrate; an adhesive layer provided between the base and the electrostatic chuck and configured to bond the base to the electrostatic chuck; and a protective member including a main body surrounding an outer periphery of the adhesive layer and configured to protect the adhesive layer, and a magnetic field generator provided in the main body and configured to generate a magnetic field in an outer peripheral portion of the substrate and around the substrate.

### CROSS-REFERENCE TO RELATED APPLICATION

This application is based upon and claims the benefit of priority from Japanese Patent Application No. 2022-204837, filed on Dec. 21, 2022, the entire contents of which are incorporated herein by reference.

### TECHNICAL FIELD

The present disclosure relates to a substrate support and a plasma processing apparatus.

### BACKGROUND

For example, Japanese Laid-open Patent Publication No. 2000-036486 discloses that an electromagnet is disposed below a focus ring provided around a substrate, and an etching rate in an outermost periphery of the substrate is controlled by the electromagnet. U.S. patent publication No. 2018/0286638 discloses that a lead wire is embedded in a susceptor, and a DC current is supplied from a DC power source to the lead wire, thereby flowing the DC current through the lead wire and forming a magnetic field immediately above an outer edge of a substrate. U.S. patent publication No. 2020/0395196 discloses that a direct-current voltage is applied to a ring-shaped ferromagnetic core unit disposed an around electrostatic chuck to adjust a magnetic field in an outer peripheral portion of a substrate.

### SUMMARY

The present disclosure provides a technique capable of controlling a magnetic field in an outer peripheral portion of a substrate while protecting an adhesive layer of a substrate support.

According to an aspect of the present disclosure, there is provided a substrate support including: a base; an electrostatic chuck provided on the base and having a substrate support surface for supporting a substrate; an adhesive layer provided between the base and the electrostatic chuck and configured to bond the base to the electrostatic chuck; and a protective member including a main body surrounding an outer periphery of the adhesive layer and configured to protect the adhesive layer, and a magnetic field generator provided in the main body and configured to generate a magnetic field in an outer peripheral portion of the substrate and around the substrate.

### BRIEF DESCRIPTION OF THE DRAWINGS

FIG. 1 is a view illustrating an example of a configuration of a plasma processing system according to an embodiment.

FIG. 2 is a schematic cross-sectional view illustrating an example of a plasma processing apparatus according to the embodiment.

FIGS. 3A and 3B are views illustrating examples of a protective member disposed in a substrate support according to the embodiment.

FIGS. 4A and 4B are enlarged views of the vicinity of the protective member according to the embodiment.

FIGS. 5A and 5B are views illustrating a magnetic field generated by a magnetic field generator of the protective member according to the embodiment.

FIGS. 6A to 6D are views illustrating examples of a method of imparting magnetism to the protective member according to the embodiment.

FIG. 7 is a view illustrating examples of a function, a material, and a type of the protective member according to the embodiment.

FIG. 8 is a view illustrating a method of installing the protective member according to the embodiment.

### DETAILED DESCRIPTION

Hereinafter, embodiments for implementing the present disclosure will be described with reference to the drawings. In the respective drawings, the same components will be denoted by the same reference numerals, and overlapping descriptions thereof may be appropriately omitted.

In the present specification, deviations in directions such as parallel, right-angled, orthogonal, horizontal, perpendicular, upper and lower, and left and right are allowed to the extent that does not impair effects of the embodiments. A shape of a corner portion is not limited to a right angle, and may be rounded in an arcuate shape. Parallel, right-angled, orthogonal, horizontal, perpendicular, circular, and coincident may include substantially parallel, substantially right-angled, substantially orthogonal, substantially horizontal, substantially perpendicular, substantially circular, and substantially coincident.

### [Plasma Processing System]

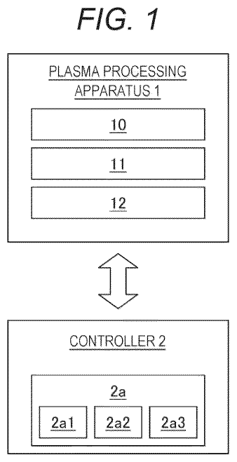

FIG. 1 is a view illustrating an example of a configuration of a plasma processing system according to an embodiment. In an embodiment, a plasma processing system includes a plasma processing apparatus 1 and a controller 2.

The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas into the plasma processing space, and at least one gas exhaust port for exhausting the gas from the plasma processing space. The gas supply port is connected to a gas supply 20 which will be described later, and the gas exhaust port is connected to an exhaust system 40 which will be described later. The substrate support 11 is disposed in the plasma processing space and has a substrate support surface for supporting a substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave-excited plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2a1, a storage unit 2a2, and a communication interface 2a3. The controller 2 is implemented by, for example, a computer 2a. The processor 2al may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2al. The medium may be various storing media readable by the computer 2a, or may be a communication line connected to the communication interface 2a3. The processor 2al may be a Central Processing Unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

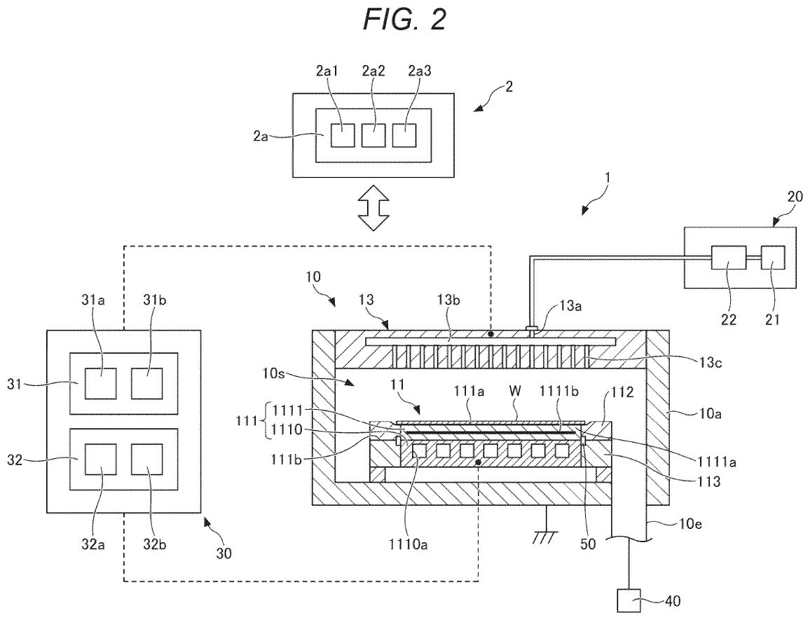

Hereinafter, a configuration example of a capacitively-coupled plasma processing apparatus as an example of the plasma processing apparatus 1 will be described. FIG. 2 is a view for explaining an example of a configuration of a capacitively-coupled plasma processing apparatus.

The capacitively-coupled plasma processing apparatus 1 includes the plasma processing chamber 10, the gas supply 20, a power source 30, and the exhaust system 40. Further, the plasma processing apparatus 1 includes the substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a substrate main body 111, a ring assembly including an edge ring 112, and an insulator ring 113. The substrate main body 111 includes a central region 111a for supporting a substrate W. The insulator ring 113 includes an annular region 111b for supporting the edge ring 112. A wafer is an example of the substrate W. The annular region 111b of the insulator ring 113 surrounds the central region 111a of the substrate main body 111 in a plan view. The substrate W is disposed on the central region 111a of the substrate main body 111, and the edge ring 112 is disposed on the annular region 111b of the insulator ring 113 to surround the substrate W on the central region 111a of the substrate main body 111. Accordingly, the central region 111a is also referred to as a substrate support surface for supporting the substrate W, and the annular region 111b is also referred to as a ring support surface for supporting the edge ring 112.

In the embodiment, the substrate main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. Other members that surround the electrostatic chuck 1111, such as an annular electrostatic chuck and an annular insulating member, may have the annular region 111b. In this case, the ring assembly may be disposed on the annular electrostatic chuck or the annular insulating member, or may be disposed on both the electrostatic chuck 1111 and the annular insulating member. Further, at least one RF/DC electrode coupled to an RF power source 31 and/or a DC power source 32 to be described later may be disposed in the ceramic member 1111a. In this case, at least one RF/DC electrode functions as the lower electrode. In a case where a bias RF signal and/or a DC signal to be described later are supplied to the at least one RF/DC electrode, the RF/DC electrode is also referred to as a bias electrode. The conductive member of the base 1110 and the at least one RF/DC electrode may function as a plurality of lower electrodes. Further, the electrostatic electrode 1111b may function as the lower electrode. Accordingly, the substrate support 11 includes at least one lower electrode.

The ring assembly includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include at least one flow rate modulation device that modulates or pulses the flow rate of at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. As a result, plasma is formed from at least one processing gas supplied into the plasma processing space 10s. Accordingly, the RF power source 31 may function as at least a part of the plasma generator 12. Further, supplying the bias RF signal to at least one lower electrode can generate a bias potential in the substrate W to attract an ionic component in the formed plasma to the substrate W.

In the embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power source 30 may include the DC power source 32 coupled to the plasma processing chamber 10. The DC power source 32 includes a first DC generator 32a and a second DC generator 32b. In one embodiment, the first DC generator 32a is configured to be connected to at least one lower electrode to generate the first DC signal. The generated first DC signal is applied to at least one lower electrode. In one embodiment, the second DC generator 32b is configured to be connected to at least one upper electrode to generate a second DC signal. The generated second DC signal is applied to at least one upper electrode.

In various embodiments, the first and second DC signals may be pulsed. In this case, the sequence of voltage pulses is applied to at least one lower electrode and/or at least one upper electrode. The voltage pulse may have a pulse waveform of a rectangle, a trapezoid, a triangle or a combination thereof. In one embodiment, a waveform generator for generating a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

### [Protective Member]

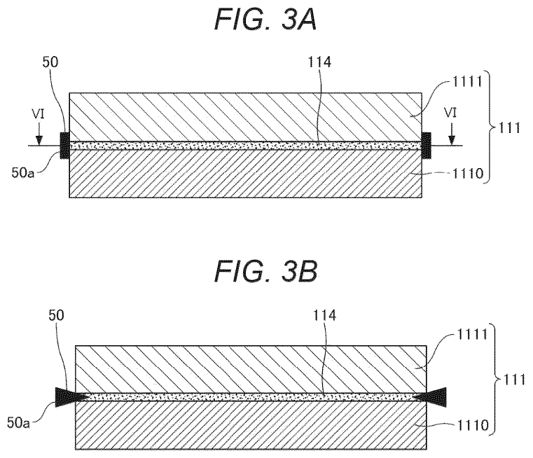

A protective member 50 will be described with reference to FIGS. 3A and 3B. FIGS. 3A and 3B are views illustrating examples of the protective member 50 disposed in the substrate support 11 according to the embodiment. The protective member 50 has an annular shape and is disposed along outer peripheral side surfaces of the base 1110 and the electrostatic chuck 1111 of the substrate main body 111 in a circumferential direction over the entire circumference.

As illustrated in FIGS. 3A and 3B, the electrostatic chuck 1111 is disposed on the base 1110 with an adhesive layer 114 interposed therebetween. The adhesive layer 114 bonds the base 1110 to the electrostatic chuck 1111.

The base 1110 and the electrostatic chuck 1111 have a disc shape having approximately the same diameter. The protective member 50 includes a main body 50a having a rectangular cross section in a radial direction. The protective member 50 includes the main body 50a, and in the protective member 50 illustrated in FIG. 3A, the cross section of the main body 50a is rectangular (square shape or rectangular shape).

The main body 50a is disposed along the outer peripheral side surfaces of the base 1110 and the electrostatic chuck 1111, and surrounds an outer periphery of the adhesive layer 114. The main body 50a is in contact with the base 1110, the electrostatic chuck 1111, and the adhesive layer 114. The main body 50a surrounds the outer periphery of the adhesive layer 114 and prevents the adhesive layer 114 between the base 1110 and the electrostatic chuck 1111 from being exposed to the plasma processing space 10s, thereby avoiding the plasma from entering the adhesive layer 114. Accordingly, it is possible to prevent the adhesive layer 114 from being eroded by the plasma, and to protect the adhesive layer 114. In the example illustrated in FIG. 3A, the main body 50a is in contact with the adhesive layer 114. Alternatively, the main body 50a may not be in contact with the adhesive layer 114. In this case, an outer peripheral surface of the adhesive layer 114 is disposed on an inner peripheral side than the outer peripheral side surfaces of the base 1110 and the electrostatic chuck 1111.

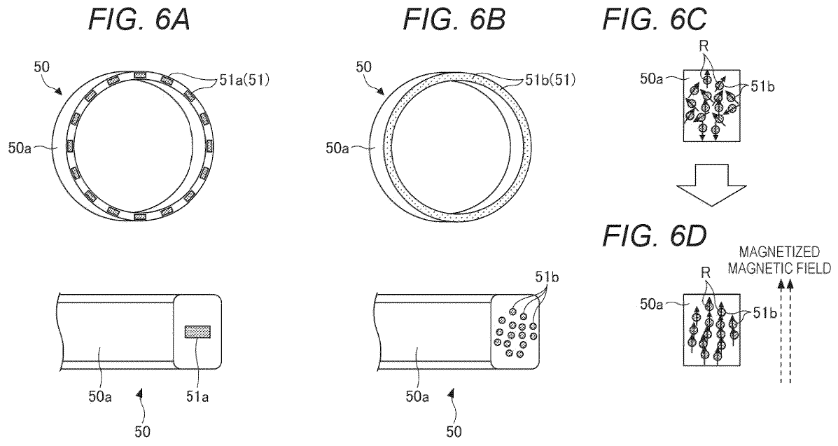

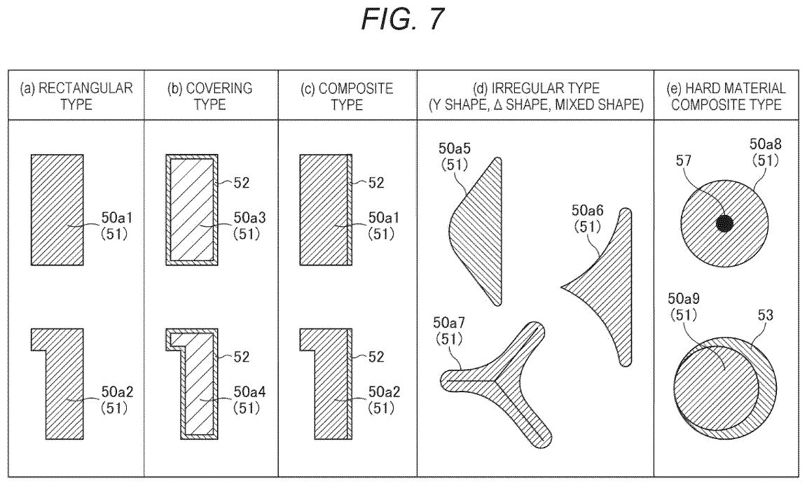

The protective member 50 includes a magnetic field generator 51 that is provided in the main body 50a and that generates a magnetic field in an outer peripheral portion of the substrate W and around the substrate W. The magnetic field generator 51 will be described later with reference to FIGS. 6A to 6D and 7 and the like.

As illustrated in FIG. 3B, the protective member 50 may have an annular shape, and include the main body 50a having a triangular shape (wedge shape) that tapers inward. A cross section of the main body 50a is thick on the outer side and thinner toward the inner side. An inner peripheral side of the main body 50a is inserted into the adhesive layer 114. In the example illustrated in FIG. 3B, the main body 50a has a triangular shape. However, the present disclosure is not limited thereto. The cross section of the main body 50a does not need to be triangular as long as the cross section is thick on the outer side and thin on the inner side.

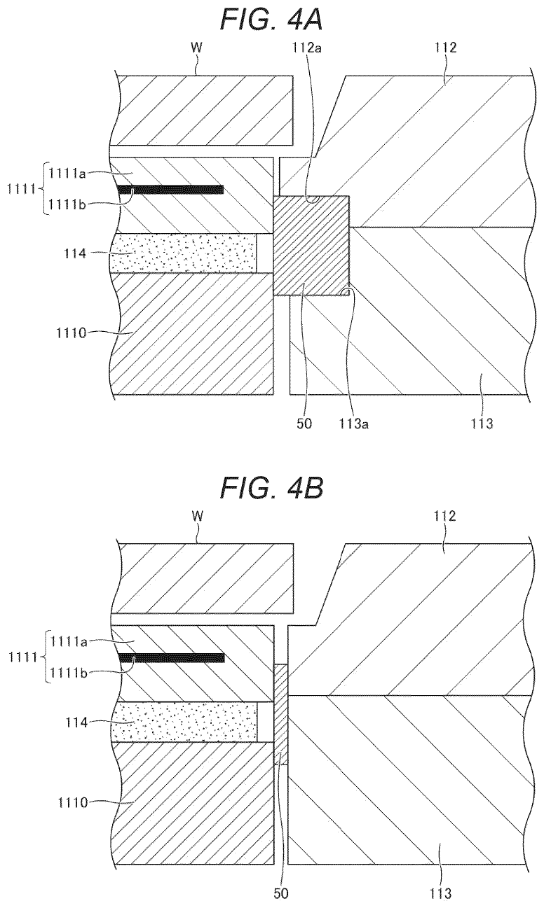

FIGS. 4A and 4B are enlarged views of the protective member 50 and the vicinity thereof according to the embodiment. The protective member 50 is an elastic member that protects the adhesive layer 114 between the electrostatic chuck 1111 (ceramic member 1111a) and the aluminum base 1110.

In the example in FIG. 4A, a recess 112a is formed in a corner portion at a lower inner periphery of the edge ring 112 facing the electrostatic chuck 1111 (ceramic member 1111a) sandwiching the adhesive layer 114, over the entire circumference in the circumferential direction. Further, a recess 113a is formed in a corner portion at an upper inner periphery of the insulator ring 113 facing the base 1110, over the entire circumference in the circumferential direction. The protective member 50 is disposed in the recess 112a and the recess 113a, and thus comes into contact with the outer peripheral side surfaces of the base 1110 and the electrostatic chuck 1111 that sandwich the adhesive layer 114, and is disposed over the entire circumference along outer peripheral end surfaces (side surfaces) of the electrostatic chuck 1111 and the base 1110.

The protective member 50 is sandwiched between the recesses 112a and 113a, and covers the adhesive layer 114 over the entire circumference in the circumferential direction in a state in which the protective member 50 is in contact with the outer peripheral end surfaces (side surfaces) of the electrostatic chuck 1111 and the base 1110. The protective member 50 is formed of a rubber material (elastic member). A function of the protective member 50 serving as a rubber band avoids the adhesive layer 114 from being exposed to plasma and being eroded.

The protective member 50 is disposed at a position where the protective member 50 is not exposed above the edge ring 112. Accordingly, it is possible to avoid the protective member 50 from being exposed to plasma.

The recesses 112a and 113a may not be formed in the edge ring 112 and the insulator ring 113. As in the example in FIG. 4B, the protective member 50 may be disposed to be sandwiched by an inner peripheral side surface of the edge ring 112 and an inner peripheral side surface of the insulator ring 113, and to seal a space of the adhesive layer 114 in a state in which the protective member 50 is in contact with the inner peripheral side surface of the edge ring 112 and the inner peripheral side surface of the insulator ring 113.

### [Magnetic Field Generator]

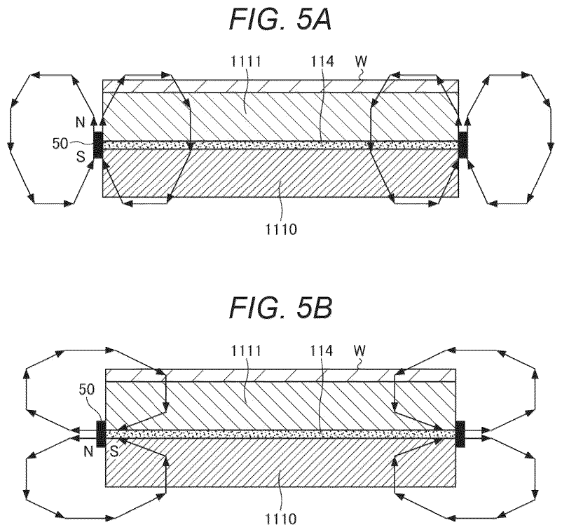

The protective member 50 according to the embodiment includes the magnetic field generator 51 (see FIGS. 6A to 6D and 7 to be described later). FIGS. 5A and 5B are views illustrating states of a magnetic field generated by the magnetic field generator 51 of the protective member 50 according to the embodiment. A magnetic force that flows from an N pole to an S pole of the protective member 50 acts around the magnetic field generator 51 (protective member 50). Arrows coming out of the protective member 50 and returning to the protective member 50 in FIGS. 5A and 5B indicate lines of the magnetic force. Depending on disposition of the main body 50a, in a form of magnetic poles illustrated in FIG. 5A, a magnetic field generated in the outer peripheral portion of the substrate W or around the substrate W can be formed perpendicularly to a radial direction of the substrate W. Further, in a form of magnetic poles illustrated in FIG. 5B, a magnetic field generated in the outer peripheral portion of the substrate W or around the substrate W can be formed in parallel to the radial direction of the substrate W.

When the substrate W is etched in the plasma processing apparatus 1, an etching rate in the outer peripheral portion of the substrate W may be locally lower than an etching rate in a substrate W region inward of the outer peripheral portion.

In contrast, as illustrated in FIGS. 5A and 5B, a locally steady magnetic field is applied to the outer peripheral portion of the substrate W or around the substrate W from the protective member 50 including the magnetic field generator 51 (see FIGS. 6A to 6D and 7 to be described later). Accordingly, it is possible to increase a plasma density in the outer peripheral portion of the substrate W by generating a drift motion of charged particles in the outer peripheral portion of the substrate W or around the substrate W. As a result, it is possible to increase the etching rate in the outer peripheral portion of the substrate W without influencing the etching rate in the substrate W region inward of the outer peripheral portion of the substrate W, thereby avoiding the etching rate in the outer peripheral portion of the substrate W from being locally lowered.

One method of controlling the etching rate in the outer peripheral portion of the substrate W is to install a magnet at an upper portion of the shower head 13 functioning as an upper electrode to generate a magnetic field in the plasma processing chamber 10. With this method, an influence of the magnetic field occurs on substantially the entire surface of the substrate W, and it is difficult to increase the etching rate in the outer peripheral portion of the substrate W without influencing an etching rate in a region other than the outer peripheral portion of the substrate W.

Further, the protective member 50 according to the present embodiment needs to be disposed on the outer periphery of the adhesive layer 114 so as not to expose the adhesive layer 114 to plasma. When the magnetic field generator 51 is provided at a position other than a position where the protective member 50 is disposed, there may be a problem that other functions (such as a function of protecting the adhesive layer 114) cannot be ensured.

In contrast, the protective member 50 according to the embodiment can control magnetic fields in the outer peripheral portion of the substrate W and around the substrate W while protecting the adhesive layer 114 of the substrate support 11. Accordingly, it is possible to selectively increase the plasma density in the outer peripheral portion of the substrate W without limiting functions of the protective member 50. That is, it is possible to increase the etching rate in the outer peripheral portion of the substrate W without influencing the etching rate in the region other than the outer peripheral portion of the substrate W, thereby achieving uniformity of an etching process on the substrate W.

### [Method of Imparting Magnetism]

The protective member 50 includes the main body 50a and the magnetic field generator 51. Since the protective member 50 has the function of the magnetic field generator 51, a method of imparting magnetism to the protective member 50 will be described with reference to FIGS. 6A to 6D. FIGS. 6A to 6D are views illustrating examples of imparting magnetism to the main body 50a of the protective member 50 and the magnetic field generator 51 according to the embodiment.

In the protective member 50 in FIG. 6A, a plurality of solid magnets 51a are disposed at equal intervals in a circumferential direction of the annular main body 50a. Accordingly, the main body 50a has the function of the magnetic field generator 51 that generates a magnetic field. The number of solid magnets 51a to be disposed and the disposition interval are determined according to the required uniformity of the etching process.

An upper part in FIG. 6A illustrates an example of a cross-sectional perspective view when the protective member 50 illustrated in FIG. 3A is cut along a VI-VI plane. The plurality of solid magnets 51a are built in the main body 50a of the protective member 50. A lower part in FIG. 6A illustrates a cross section obtained by cutting the annular main body 50a in a radial direction. The solid magnet 51a is built in a center of the main body 50a. Orientations of magnetic poles of the plurality of solid magnets 51a are the same.

In the protective member 50 in FIG. 6A, the plurality of solid magnets 51a having the same shape and size are disposed at equal intervals in the circumferential direction. However, the present disclosure is not limited thereto. The plurality of solid magnets 51a may be disposed at unequal intervals.

When a magnitude of the magnetic field generated by the magnetic field generator 51 is about 10 G to 100 G in the plasma processing chamber 10 in vacuum (depressurized state), a plasma density in the outer peripheral portion of the substrate W can be locally increased. Examples of the solid magnet 51a include a neodymium magnet having a surface magnetic flux density of 1.3 kG or 2.8 kG. The neodymium magnet can impart a sufficient magnetic field to the magnetic field generator 51 in the main body 50a to locally increase the plasma density in the outer peripheral portion of the substrate W.

Another method of imparting magnetism to the main body 50a is to mix and knead a magnetic powder 51b in an amount sufficient to have a required magnetic force into the elastic member (rubber material) of the main body 50a (see FIG. 6B). During molding in which the magnetic powder 51b illustrated in FIG. 6C is mixed with the main body 50a, a direction R of a magnetic field is not aligned in a certain direction, and the main body 50a is not magnetized. The main body 50a is magnetized in a required direction when a temperature thereof after the molding is lowered, and after magnetization illustrated in FIG. 6D, the direction R of the magnetic field of the magnetic powder 51b mixed with the main body 50a is aligned in a direction of a magnetized magnetic field, whereby the function of the magnetic field generator 51 that generates a magnetic field is imparted to the main body 50a.

An upper part in FIG. 6B illustrates another example of the cross-sectional perspective view when the protective member 50 illustrated in FIG. 3A is cut along the VI-VI plane. The magnetic powder 51b is present in the entire main body 50a. A lower part in FIG. 6B illustrates a cross section obtained by cutting the annular main body 50a in the radial direction. The magnetic powder 51b is mixed with the main body 50a.

For example, in a case where a barium-ferrite magnetic powder is used as the magnetic powder 51b, when a barium-ferrite filling ratio in the main body 50a is, for example, about 40% or more, the surface magnetic flux density is several thousand G (gauss). This surface magnetic flux density is sufficient as a magnitude of the magnetic field generated by the magnetic field generator 51 (magnetic powder 51b) in the main body 50a, and the plasma density in the outer peripheral portion of the substrate W can be locally controlled even with the protective member 50 in FIG. 6B.

The magnetic field generator 51 in the protective member 50 may be a ferromagnetic material. The ferromagnetic material may be any one of neodymium, iron, mild steel, nickel, cobalt, and a Heusler alloy, or a combination thereof.

In the protective member 50 in FIG. 6B, the magnetic powder 51b is mixed with the elastic member of the main body 50a at a uniform density. However, the present disclosure is not limited thereto. The magnetic powder 51b may be mixed with the elastic member of the main body 50a at a non-uniform density.

### [Function, Material, and Type of Protective Member]

A function, a material, and a type of the protective member 50 according to the embodiment will be described with reference to FIG. 7. FIG. 7 is a view illustrating examples of the function, the material, and the type of the protective member 50 according to the embodiment.

Functions required for the protective member 50 according to the embodiment include “1. sealing property” for protecting the adhesive layer 114, “2. low dust generation property” for avoiding contamination in the plasma processing chamber 10, “3. magnetism” for controlling the plasma density, and “4. mountability”. FIG. 7 illustrates main bodies 50a1 to 50a9 as examples of the main body 50a of the protective member 50. The main bodies 50a1 to 50a9 are also be collectively referred to as the main body 50a. With reference to FIG. 7, the “sealing property”, the “low dust generation property”, the “magnetism”, and the “mountability” of the main bodies 50a1 to 50a9 of the protective member 50 will be described.

### (1. Sealing Property)

In order to achieve the “sealing property” of the protective member 50, the main body 50a of the protective member 50 is formed of an elastic material. The elastic material is, for example, an elastomer such as a silicone rubber. The main body 50a of the protective member 50 is formed of the elastic material, and thereby can come into contact with the outer peripheral side surfaces of the base 1110 and the electrostatic chuck 1111 sandwiching the adhesive layer 114, and can be stably disposed over the entire circumference along the outer peripheral end surfaces (side surfaces) of the electrostatic chuck 1111 and the base 1110.

### (2. Low Dust Generation Property)

In order to achieve the “low dust generation property” of the protective member 50, the main body 50a of the protective member 50 is formed of an elastomer (elastic material) having radical resistance (plasma resistance), or a covering material or a composite material having radical resistance. The covering material refers to a material obtained by covering a rubber material such as a silicone rubber with a plastic having radical resistance or a resin having radical resistance. The composite material is a composite material joining a plastic having radical resistance with a resin having radical resistance. Examples of the resin having radical resistance include a perfluoroelastomer (FFKM) material or a fluoroelastomer (ternary FKM) material. Examples of the plastic having radical resistance include a PTFE (polytetrafluoroethylene) material. The term “radical resistance” means that an amount of consumption by plasma is smaller than that of the adhesive layer 114 when exposed to plasma.

### (3. Magnetism)

In order to achieve the “magnetism” of the protective member 50, the main body 50a of the protective member 50 includes the solid magnet (FIG. 6A) having the above-described appropriate strength (surface magnetic flux density), or contains an amount of magnetic powder (FIG. 6B) for imparting appropriate strength to the main body 50a. In imparting the magnetism to the main body 50a illustrated in FIG. 6B, a magnetic field after magnetization is directed in a direction of the magnetized magnetic field (FIGS. 6C and 6D).

### (4. Mountability)

In order to achieve the “mountability” of the protective member 50, it is necessary to prevent the protective member 50 from twisting. Therefore, the protective member 50 preferably has a shape that does not easily cause twisting.

Further, when the main body 50a is formed of a rubber material (elastic member) having no plasma resistance, such as a silicone rubber, the main body 50a is consumed by plasma. Therefore, it is preferable that at least a surface of the main body 50a exposed to plasma is covered with a covering material having radical resistance.

In order to achieve the four functions of the protective member 50 described above, the main body 50a may be formed of an elastic material, and the elastic material may have radical resistance. (a) in FIG. 7 to (c) in FIG. 7 illustrate, as examples of the main body 50a, the main bodies 50al and 50a3 each having rectangular cross section in the radial direction, and the main bodies 50a2 and 50a4 each having an L-shaped cross section in the radial direction.

The main body 50al and the main body 50a2 in (a) in FIG. 7 are each formed of an elastic member having plasma resistance, and thus can function as the protective member 50 even without being covered with a covering material. The elastic material may be a perfluoroelastomer (FFKM) material or a fluoroelastomer (ternary FKM) material. The main body 50a1 and the main body 50a2 are imparted with magnetism by the method of imparting magnetism in FIG. 6A or 6B. That is, each of the main body 50al and the main body 50a2 includes the magnetic field generator 51.

The main body 50a may be formed of an elastic material having no radical resistance, and a surface of the elastic material may be entirely covered with a covering material having radical resistance. The main body 50a3 and the main body 50a4 in (b) in FIG. 7 are each formed of an elastic member having no plasma resistance, such as a silicone rubber, and are thus easily consumed when exposed to plasma. In this case, the entire surface of each of the elastic members of the main body 50a3 and the main body 50a4 is covered (coated) with a covering material 52 having radical resistance. The main body 50a3 and the main body 50a4 are imparted with magnetism by the method of imparting magnetism in FIG. 6A or 6B. That is, each of the main body 50a3 and the main body 50a4 includes the magnetic field generator 51.

The main body 50a may be formed of an elastic material, the elastic material may have radical resistance, and a surface of the elastic material may be partially or entirely covered with a covering material having radical resistance. The main body 50al and the main body 50a2 in (c) in FIG. 7 are formed of an elastic member having plasma resistance, and thus can function as the protective member 50 even without being covered with a covering material. In this case, a surface of each of the elastic members of the main body 50a1 and the main body 50a2 may also be partially or entirely covered with the covering material 52 having radical resistance. The covering material 52 may cover a surface of the main body 50a2 other than a surface in contact with the electrostatic chuck 1111 and the base 1110 to protect the adhesive layer 114. Accordingly, it is possible to further ensure elasticity for protecting the adhesive layer 114 while improving the radical resistance and the plasma resistance.

A cross section of the annular main body 50a in the radial direction may be formed in a wedge shape, a triangular shape, or a Y shape. The main bodies 50a5, 50a6, and 50a7 in (d) in FIG. 7 are other examples of the main body 50a formed of an elastic member having plasma resistance. The main bodies 50a5, 50a6, and 50a7 are each formed of the elastic member having plasma resistance, and thus can function as the protective member 50 even without being covered with a covering material. However, a surface of each of the main bodies 50a5, 50a6, and 50a7 may be partially or entirely covered with a covering material.

A cross section of the main body 50a5 in the radial direction is formed in a wedge shape. A cross section of the main body 50a6 in the radial direction is formed in a substantially triangular shape in which one corner portion is pointed and the remaining corner portions are round (referred to as a triangular shape). A cross section of the main body 50a7 in the radial direction is formed in a substantially Y shape (referred to as a “Y shape”).

Parts (corner portions) of the main bodies 50a5, 50a6, and 50a7 may be inserted into the adhesive layer 114 (see FIG. 3B). The main bodies 50a5, 50a6, and 50a7 are imparted with magnetism by the method of imparting magnetism in FIG. 6A or 6B. That is, each of the main bodies 50a5, 50a6, and 50a7 includes the magnetic field generator 51.

For example, the main body 50a8 illustrated in (e) in FIG. 7 is formed of an elastic material, the elastic material has more radical resistance than the adhesive layer 114, and a core member 57 is embedded at a center of the main body 50a8 in the circumferential direction. In this configuration, twisting does not occur in the main body 50a, and thus the main body 50a can function as the protective member 50. An elastic modulus of the core member 57 is preferably 10 GPa or more.

Further, in a configuration in which the main body 50a9 illustrated in (e) in FIG. 7 is formed of an elastic material, the elastic material has radical resistance, and a surface of the elastic material of the main body 50a9 is partially or entirely covered with a covering material 53 having an elastic modulus of 300 MPa or more, twisting does not occur in the main body 50a. Therefore, the protective member 50 is implemented.

In the example of the main body 50a9, the covering material 53 may not cover a surface of the main body 50a9 that comes into contact with the electrostatic chuck 1111 and the base 1110 but cover an opposite surface thereof to protect the adhesive layer 114. Accordingly, it is possible to further ensure elasticity for protecting the adhesive layer 114 while preventing the main body 50a from twisting.

### [Method of Installing Protective Member]

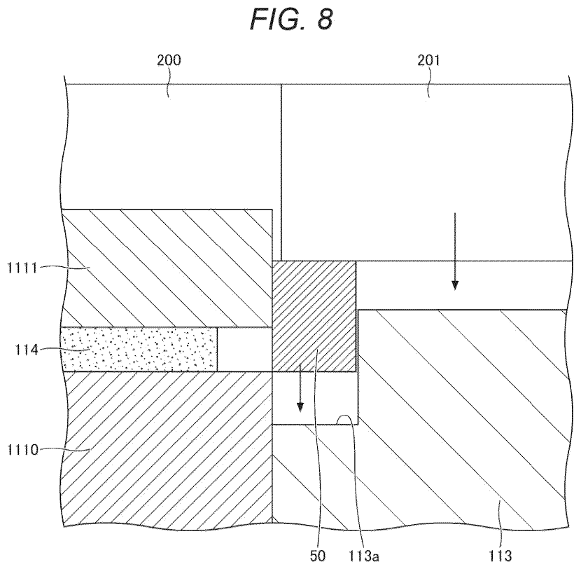

A method of installing the protective member 50 will be described with reference to FIG. 8. FIG. 8 is a view illustrating the method of installing the protective member 50 according to the embodiment.

For the protective member 50, a guide jig 200 is prepared on the electrostatic chuck 1111 in a state in which the edge ring 112 is not placed on the insulator ring 113. The guide jig 200 has a disc shape and is positioned on the electrostatic chuck 1111 by a depending portion protruding downward along a corner portion on an upper outer peripheral portion of the electrostatic chuck 1111. A vertical movement of a pressing jig 201 is guided by the guide jig 200.

The pressing jig 201 has an annular shape and is provided around the guide jig 200 to push the protective member 50 downward along a side surface of the guide jig 200 and fit the protective member 50 into the recess 113a of the insulator ring 113. Accordingly, the protective member 50 can be installed in the recess 113a of the insulator ring 113. After the protective member 50 is installed, the edge ring 112 is placed on the insulator ring 113, and an upper portion of the protective member 50 is fitted into the recess 112a of the edge ring 112. Accordingly, the protective member 50 can be installed in a state in FIG. 4A.

The embodiments disclosed above include, for example, the following aspects.

### (Appendix 1)

A substrate support including:
a base;
an electrostatic chuck provided on the base and having a substrate support surface for supporting a substrate;
an adhesive layer provided between the base and the electrostatic chuck and configured to bond the base to the electrostatic chuck; and
a protective member including a main body surrounding an outer periphery of the adhesive layer and configured to protect the adhesive layer, and a magnetic field generator provided in the main body and configured to generate a magnetic field in an outer peripheral portion of the substrate and around the substrate.

### (Appendix 2)

In the substrate support according to Appendix 1,

the magnetic field generator generates the magnetic field by a solid magnet embedded in the main body.

### (Appendix 3)

In the substrate support according to Appendix 1,

the magnetic field generator generates the magnetic field by a magnetic powder in the main body.

### (Appendix 4)

In the substrate support according to any one of Appendices 1 to 3,

the magnetic field generator generates the magnetic field perpendicularly to or in parallel to a radial direction of the substrate in the outer peripheral portion of the substrate and around the substrate.

### (Appendix 5)

In the substrate support according to any one of Appendices 1 to 4,

the main body is formed in an annular shape, and

a cross section of the main body in a radial direction is formed in a rectangular shape or an L shape.

### (Appendix 6)

In the substrate support according to any one of Appendices 1 to 4,

the main body is formed in an annular shape,

a cross section of the main body in a radial direction is formed in a wedge shape, a triangle shape, or a Y shape, and

a part of the main body is embedded in the adhesive layer.

### (Appendix 7)

In the substrate support according to Appendix 6,

the main body is formed in a wedge shape that tapers inward, and

an inner peripheral side of the main body is embedded in the adhesive layer.

### (Appendix 8)

In the substrate support according to any one of Appendices 1 to 7,

the main body is formed of an elastic material, and

the elastic material has more radical resistance than the adhesive layer.

### (Appendix 9)

In the substrate support according to any one of Appendices 1 to 7,

the main body is formed of an elastic material, and

the elastic material is entirely covered with a covering material having more radical resistance than the adhesive layer.

### (Appendix 10)

In the substrate support according to any one of Appendices 1 to 7,

the main body is formed of an elastic material,

the elastic material has more radical resistance than the adhesive layer, and

a surface of the elastic material is partially or entirely covered with a covering material having more radical resistance than the adhesive layer.

### (Appendix 11)

In the substrate support according to any one of Appendices 1 to 4,

the main body is formed in an annular shape,

a cross section of the main body in a radial direction is formed in a circular shape,

the main body is formed of an elastic material,

the elastic material has more radical resistance than the adhesive layer, and

a core member is provided at a center of the main body in a circumferential direction.

### (Appendix 12)

In the substrate support according to any one of Appendices 1 to 4,

the main body is formed in an annular shape,

a cross section of the main body in a radial direction is formed in a circular shape,

the main body is formed of an elastic material,

the elastic material has more radical resistance than the adhesive layer, and

a surface of the elastic material is partially or entirely covered with a covering material having an elastic modulus of 300 MPa or more.

### (Appendix 13)

In the substrate support according to Appendix 8, 10, or 11,

the elastic material is a perfluoroelastomer (FFKM) material or a fluoroelastomer (ternary FKM) material.

### (Appendix 14)

In the substrate support according to any one of Appendices 1 to 13,

the magnetic field generator is a ferromagnetic material.

### (Appendix 15)

In the substrate support according to Appendix 14,

the ferromagnetic material is any one of neodymium, iron, mild steel, nickel, cobalt, and a Heusler alloy, or combination thereof.

### (Appendix 16)

A plasma processing apparatus for plasma-processing a substrate, the apparatus including:

a processing chamber;

a substrate support provided in the processing chamber and configured to support the substrate;

a gas supply configured to supply a gas into the processing chamber; and

a plasma generator configured to supply RF power into the processing chamber and generate plasma from the gas, in which

the substrate support includes

a base,

an electrostatic chuck provided on the base and having a substrate support surface for supporting the substrate,

an adhesive layer provided between the base and the electrostatic chuck and configured to bond the base to the electrostatic chuck, and

a protective member including a main body surrounding an outer periphery of the adhesive layer and configured to protect the adhesive layer, and a magnetic field generator provided in the main body and configured to generate a magnetic field in an outer peripheral portion of the substrate and around the substrate.

1. A substrate support comprising:
a base;
an electrostatic chuck provided on the base and having a substrate support surface for supporting a substrate;
an adhesive layer provided between the base and the electrostatic chuck and configured to bond the base to the electrostatic chuck; and
a protective member including a main body surrounding an outer periphery of the adhesive layer and configured to protect the adhesive layer, and a magnetic field generator provided in the main body and configured to generate a magnetic field in an outer peripheral portion of the substrate and around the substrate.

2. The substrate support according to claim 1, wherein
the magnetic field generator generates the magnetic field by a solid magnet embedded in the main body.

3. The substrate support according to claim 1, wherein
the magnetic field generator generates the magnetic field by a magnetic powder in the main body.

4. The substrate support according to claim 1, wherein
the magnetic field generator generates the magnetic field perpendicularly to or in parallel to a radial direction of the substrate in the outer peripheral portion of the substrate and around the substrate.

5. The substrate support according to claim 1, wherein
the main body is formed in an annular shape, and
a cross section of the main body in a radial direction is formed in a rectangular shape or an L shape.

6. The substrate support according to claim 1, wherein
the main body is formed in an annular shape,
a cross section of the main body in a radial direction is formed in a wedge shape, a triangle shape, or a Y shape, and
a part of the main body is embedded in the adhesive layer.

7. The substrate support according to claim 6, wherein
the main body is formed in a wedge shape that tapers inward, and
an inner peripheral side of the main body is embedded in the adhesive layer.

8. The substrate support according to claim 1, wherein
the main body is formed of an elastic material, and
the elastic material has more radical resistance than the adhesive layer.

9. The substrate support according to claim 1, wherein
the main body is formed of an elastic material, and
the elastic material is entirely covered with a covering material having more radical resistance than the adhesive layer.

10. The substrate support according to claim 1, wherein
the main body is formed of an elastic material,
the elastic material has more radical resistance than the adhesive layer, and
a surface of the elastic material is partially or entirely covered with a covering material having more radical resistance than the adhesive layer.

11. The substrate support according to claim 1, wherein
the main body is formed in an annular shape,
a cross section of the main body in a radial direction is formed in a circular shape,
the main body is formed of an elastic material,
the elastic material has more radical resistance than the adhesive layer, and
a core member is provided at a center of the main body in a circumferential direction.

12. The substrate support according to claim 1, wherein
the main body is formed in an annular shape,
a cross section of the main body in a radial direction is formed in a circular shape,
the main body is formed of an elastic material,
the elastic material has more radical resistance than the adhesive layer, and
a surface of the elastic material is partially or entirely covered with a covering material having an elastic modulus of 300 MPa or more.

13. The substrate support according to claim 8, wherein
the elastic material is a perfluoroelastomer (FFKM) material or a fluoroelastomer (ternary FKM) material.

14. The substrate support according to claim 1, wherein
the magnetic field generator is a ferromagnetic material.

15. The substrate support according to claim 14, wherein
the ferromagnetic material is any one of neodymium, iron, mild steel, nickel, cobalt, and a Heusler alloy, or a combination thereof.

16. A plasma processing apparatus for plasma-processing a substrate, the apparatus comprising:
a processing chamber;
a substrate support provided in the processing chamber and configured to support the substrate;
a gas supply configured to supply a gas into the processing chamber; and
a plasma generator configured to supply RF power into the processing chamber and generate plasma from the gas, wherein
the substrate support includes
a base,
an electrostatic chuck provided on the base and having a substrate support surface for supporting the substrate,
an adhesive layer provided between the base and the electrostatic chuck and configured to bond the base to the electrostatic chuck, and
a protective member including a main body surrounding an outer periphery of the adhesive layer and configured to protect the adhesive layer, and a magnetic field generator provided in the main body and configured to generate a magnetic field in an outer peripheral portion of the substrate and around the substrate.
